(19) United States
(12) Patent Application Publication
(10) Pub. No.: US 2026/0309787 A1
(43) Pub. Date: Oct. 8, 2026

(54) METHOD AND APPARATUS FOR DIAGNOSING STATE OF BATTERY USING NEURAL NETWORK MODEL

(71) Applicant: Samsung SDI Co., Ltd., Yongin-si (KR)

(72) Inventor: Kwanghum Park, Yongin-si (KR)

(73) Assignee: Samsung SDI Co., Ltd., Yongin-si (KR)

(21) Appl. No.: 19/629,523

(22) Filed: Mar. 26, 2026

(30) Foreign Application Priority Data
Apr. 8, 2025 (KR) 10-2025-0045740

(51) Int. Cl. G01R 31/367; G01R 31/389; G01R 31/392; G06N 3/08

(52) U.S. Cl. CPC G01R 31/367; G01R 31/389; G01R 31/392; G06N 3/08

(57) ABSTRACT

A method and apparatus for diagnosing a state of a battery includes measuring electrochemical feature data of all of frequency regions of the battery, training a neural network model that estimates the state of the battery in the measured electrochemical feature data, identifying a frequency region having a high contribution to a prediction of the state of the battery based on a feature map by using the trained neural network model, reducing a data dimension of the frequency region by extracting the electrochemical feature data of the identified frequency region, retraining the neural network model by using electrochemical feature data of the reduced frequency region, and diagnosing the state of the battery by using the retrained neural network model.

### CROSS-REFERENCE TO RELATED APPLICATIONS

This present application claims priority to and the benefit under 35 U.S.C. § 119(a)-(d) of Korean Patent Application No. 10-2025-0045740, filed on Apr. 8, 2025, in the Korean Intellectual Property Office, the entire disclosure of which is incorporated herein by reference.

### FIELD

The present disclosure relates to a technical field in which the state of a battery is evaluated and more particularly to a method and apparatus for diagnosing the state of a battery using a retrained neural network model, which estimate the state of health (SOH) of a battery more accurately and rapidly.

### BACKGROUND

A secondary battery is a battery that can be charged and discharged, unlike a primary battery that is not rechargeable. Low-capacity secondary batteries are used in portable small electronic devices such as smartphones, feature phones, laptop computers, digital cameras, and camcorders, whereas high-capacity secondary batteries are widely used as power sources for driving motors in hybrid vehicles and electric vehicles, as well as in power storage batteries. A secondary battery includes an electrode assembly having a positive electrode and a negative electrode, a case accommodating the electrode assembly, and electrode terminals connected to the electrode assembly.

As described herein, the secondary battery is used as a core power supply source in various industries, such as an electric vehicle (EV), an energy storage system (ESS), and portable electronic devices. Performance and the lifespan of a battery are gradually decreased as the battery is used for a long time. Accordingly, a technique in which the state of the battery is accurately evaluated is essentially required.

In particular, the state of health (SOH) of the battery is an important indicator representing the degree of a performance reduction level of the battery. To accurately evaluate the SOH is essential to secure an efficient operation and safety of the battery. A method of analyzing the voltage, current, and charging/discharging pattern of the battery is basically used as the existing SOH evaluation method. However, such a method has limitations in that complex chemical or physical changes occurring within the battery are not directly reflected.

The herein-described information disclosed in the background technology of the disclosure is provided only to enhance understanding of the background of the present disclosure, and therefore may include information that does not constitute prior art.

### SUMMARY

A method of diagnosing a state of a battery using an apparatus for diagnosing the state of the battery according to embodiments Of the present may include measuring electrochemical feature data of all of frequency regions of the battery, training a neural network model that estimates the state of the battery in the measured electrochemical feature data, identifying a frequency region having a high contribution to a prediction of the state of the battery based on a feature map by using the trained neural network model, reducing a data dimension of the frequency region by extracting the electrochemical feature data of the identified frequency region, retraining the neural network model by using electrochemical feature data of the reduced frequency region, and diagnosing the state of the battery by using the retrained neural network model.

According to embodiments of the present disclosure, the measuring of the electrochemical feature data may include measuring electrochemical impedance spectroscopy (EIS) data and generating impedance data having a complex number form by measuring impedance of the entire frequency range of the battery.

According to embodiments of the present disclosure, the training of the neural network model may include estimating the state of the battery by using the state of health (SOH) data of the battery and the electrochemical feature data as an input.

According to embodiments of the present disclosure, the training of the neural network model may include normalizing input data for the neural network model by reflecting the state of charge (SOC) and temperature condition of the battery.

According to embodiments of the present disclosure, the identifying of the frequency region based on the feature map may include identifying the frequency region based on a class activation map (CAM) and selecting a frequency point having a high contribution to a prediction of the SOH through analysis based on a CAM score of the trained neural network model.

According to embodiments of the present disclosure, the identifying of the frequency region based on the feature map may include selecting the frequency point so that the SOH is able to be reliably predicted even in a specific SOC condition by reflecting an impedance feature according to a change in SOC of the battery.

According to embodiments of the present disclosure, the reducing of the data dimension of the frequency region by extracting the electrochemical feature data of the identified frequency region may include removing unnecessary data in the identified frequency region and reducing a data dimension by using only selected frequency points.

According to embodiments of the present disclosure, the retraining of the neural network model by using the electrochemical feature data of the reduced frequency region may include retraining the neural network model by using a reduced dataset and verifying prediction performance of the SOH of the battery.

According to embodiments of the present disclosure, the retraining of the neural network model may include performing the retraining in a way to minimize an error of the prediction of the SOH by comparing and evaluating performance of the existing neural network model and performance of a neural network model using the reduced dataset.

According to embodiments of the present disclosure, the diagnosing of the state of the battery by using the retrained neural network model may include predicting SOH of the battery by receiving the electrochemical feature data of the reduced frequency region as an input and analyzing the degradation state of the battery based on the SOH.

An apparatus for diagnosing the state of a battery according to embodiments of the present disclosure may include an electrochemical feature data measurement module configured to measure EIS data of all of frequency regions of the battery, a model training module configured to train a neural network model that estimates the state of the battery in the measured electrochemical feature data, a frequency identification module configured to identify a frequency region having a high contribution to a prediction of the state of the battery based on a feature map by using the trained neural network model, a data dimension reduction module configured to reduce a data dimension of the frequency region by extracting the electrochemical feature data of the identified frequency region, a model retraining module configured to retrain the neural network model by using electrochemical feature data of the reduced frequency region, and an SOH diagnosis module configured to diagnose the state of the battery by using the retrained neural network model.

According to embodiments of the present disclosure, the electrochemical feature data measurement module may measure EIS data and generate impedance data having a complex number form by measuring impedance of the entire frequency range of the battery.

According to embodiments of the present disclosure, the model training module may include a neural network model that estimates the state of the battery by using the SOH data of the battery and the electrochemical feature data as an input.

According to embodiments of the present disclosure, the model training module may normalize input data for the neural network model by reflecting an SOC and temperature condition of the battery.

According to embodiments of the present disclosure, the frequency identification module may identify the frequency region based on a CAM and select a frequency point having a high contribution to a prediction of the SOH through analysis based on a CAM score of the trained neural network model.

According to embodiments of the present disclosure, the frequency identification module may select the frequency point SO that the SOH is able to be reliably predicted even in a specific SOC condition by reflecting an impedance feature according to a change in SOC of the battery.

According to embodiments of the present disclosure, the data dimension reduction module may remove unnecessary data in the identified frequency region and reduce a data dimension by using only selected frequency points.

According to embodiments of the present disclosure, the model retraining module may retrain the neural network model by using a reduced dataset and verify prediction performance of the SOH of the battery.

According to embodiments of the present disclosure, the model retraining module may perform the retraining in a way to minimize an error of the prediction of the SOH by comparing and evaluating performance of the existing neural network model and performance of a neural network model using the reduced dataset.

According to embodiments of the present disclosure, the SOH diagnosis module may predict SOH of the battery by receiving the electrochemical feature data of the reduced frequency region as an input and analyze the degradation state of the battery based on the SOH.

### BRIEF DESCRIPTION OF THE DRAWINGS

The following drawings attached to this specification illustrate preferred embodiments of the present disclosure, and help to further understand the technical spirit of the present disclosure along with the aforementioned contents of the disclosure. Accordingly, the present disclosure should not be construed as being limited to only contents described in such drawings:

FIG. 1 is a schematic diagram illustrating a cylindrical lithium secondary battery according to an implementation example.

FIG. 2 is a schematic diagram illustrating a prismatic lithium secondary battery according to an implementation example.

FIGS. 3 and 4 are schematic diagrams illustrating a pouch type lithium secondary battery according to an implementation example.

FIG. 5 is a diagram illustrating a method of diagnosing the state of a battery according to embodiments of the present disclosure.

FIG. 6 is a diagram illustrating an apparatus for diagnosing the state of a battery according to embodiments of the present disclosure.

FIG. 7 is a diagram illustrating a construction of an apparatus for implementing the method of diagnosing the state of a battery according to embodiments of the present disclosure.

### DETAILED DESCRIPTION

Hereinafter, preferred embodiments of the present disclosure will be described in detail with reference to the accompanying drawings. Prior to this, terms or words used in the specification and claims should not be construed as being limited to their ordinary or dictionary meanings, but should be interpreted in accordance with the technical spirit of the present disclosure based on the principle that an inventor may appropriately define the concepts of terms in order to describe the disclosure in the best manner. Accordingly, the embodiments described in this specification and the configurations illustrated in the drawings are merely some preferred embodiments of the present disclosure and do not represent all Of the technical spirit of the present disclosure. It should therefore be understood that various equivalents and modifications that may substitute for these embodiments may exist at the time of filing of the present application.

In addition, as used herein, the terms “comprise,” “include,” and/or “comprising,” “including” specify the presence of stated features, numbers, steps, operations, members, elements, and/or groups thereof, but do not preclude the presence or addition of one or more other features, numbers, steps, operations, members, elements, and/or groups thereof.

Further, in order to facilitate understanding of the disclosure, the accompanying drawings are not necessarily drawn to scale, and the dimensions of some components may be exaggerated. In addition, identical reference numerals may be assigned to identical components in different embodiments.

A statement that two compared objects are “the same” means that they are “substantially the same.” Accordingly, “substantially the same” may include a case having a deviation that is considered minor in the art, for example, a deviation within 5%. In addition, stating that a certain parameter is uniform within a given region may mean that it is uniform in an average sense.

Although terms such as first and second may be used to describe various components, these components are not limited by such terms. These terms are used only to distinguish one component from another, and unless otherwise clearly stated, a first component may also be a second component.

Throughout the specification, unless expressly stated otherwise, each component may be singular or plural.

When an arbitrary component is described as being disposed “on (or under)” or “above (or below)” another component, this may mean not that the arbitrary component is disposed in contact with the upper (or lower) surface of the other component, but also that another component may be interposed between the two components.

In addition, when a component is described as being “on,” “connected to,” or “coupled to” another component, it should be understood that the components may be directly connected or coupled to each other, Or that another component may be interposed between them, or that the components may be connected or coupled to each other through another component.

As used herein, the term “and/or” includes any and all combinations of one or more of the associated listed items. Further, when describing embodiments of the present disclosure, the use of “may” refers to one or more embodiments of the present disclosure. Expressions such as “one or more” preceding a list of elements modify the entire list and do not modify the individual elements of the list.

Throughout the specification, the expression “a and/or B” means A, B, or A and B, unless otherwise clearly stated, and the expression “C to D” means C or more and D or less, unless otherwise clearly stated.

When phrases such as “at least one of A, B, and C,” “at least one of A, B, or C,” “at least one selected from the group consisting of A, B, and C,” or “at least one selected from among A, B, and C” are used to designate a list of elements A, B, and C, the phrase may refer to any and all suitable combinations thereof.

The term “use” may be regarded as synonymous with “utilize.” As used herein, the terms “substantially,” “about,” and similar terms are used as terms of approximation rather than terms of degree and are intended to account for inherent variations in measured or calculated values that would be recognized by those skilled in the art.

In this specification, terms such as first, second, and third may be used to describe various elements, components, regions, layers, and/or sections, but such elements, components, regions, layers, and/or sections should not be limited by these terms. These terms are used to distinguish one element, component, region, layer, or section from another. Accordingly, a first element, component, region, layer, or section discussed herein may be referred to as a second element, component, region, layer, or section without departing from the teachings of the exemplary embodiments.

Spatially relative terms such as “beneath,” “below,” “lower,” “above,” and “upper” may be used for ease of description to describe the relationship of one element or feature to another element(s) or feature(s) as illustrated in the drawings. These spatially relative terms are intended to encompass different orientations of the device in use or operation in addition to the orientation depicted in the drawings. For example, if a device shown in the drawings is turned over, elements described as “below” or “beneath” other elements would then be oriented “above” the other elements. Accordingly, the term “below” may encompass both an orientation of above and below.

The terminology used herein is for the purpose of describing embodiments of the present disclosure and is not intended to limit the present disclosure.

Lithium secondary batteries may be classified into cylindrical, prismatic, pouch-type, coin-type, and other types depending on their shape. Since the present disclosure is basically applicable to cylindrical, prismatic, and pouch-type batteries, these types of secondary batteries will be briefly described before describing embodiments of the present disclosure.

Embodiments of the present disclosure are directed to providing an apparatus and method for diagnosing the state of a battery, which can evaluate the state of a battery precisely and rapidly.

Embodiments of the present disclosure are directed to providing an apparatus and method for diagnosing the state of a battery, which can learn the state of a battery by using a neural network model, can estimate the SOH of the battery more accurately by extracting and analyzing major feature data, and can diagnose the degradation state of the battery.

According to embodiments of the present disclosure, there are provided the apparatus and method for diagnosing a state of a battery, which can evaluate the state of the battery more accurately and rapidly. It is possible to estimate the SOH of the battery based on data that are learnt based on a neural network model and to analyze the degradation state of the battery.

According to embodiments of the present disclosure, it is possible to predict the SOH of the battery with high reliability even in various environments by reflecting an influence according to the SOC and temperature change of the battery. Furthermore, it is possible to improve operation efficiency by selectively using data having a high contribution to the estimation of the SOH and increase an operation speed by reducing the data dimension of a frequency region through the analysis of a feature frequency region using a CAM.

Furthermore, it is possible to maintain the prediction accuracy of the SOH of the battery and also reduce the data processing speed by using only a specific feature frequency region compared to the existing method of analyzing all of the frequency data of a battery. The optimized evaluation of the state of a battery can be performed even in various battery types and use environments because a process of retraining a neural network model is included.

However, the effects obtainable through the present disclosure are not limited to the herein-described effects, and other technical effects not mentioned herein will be clearly understood by those skilled in the art from the following description of the disclosure. Additionally, the technical problems to be solved by the present disclosure are not limited to the herein-described problems, and other problems not mentioned herein will be clearly understood by those skilled in the art from the following description of the disclosure.

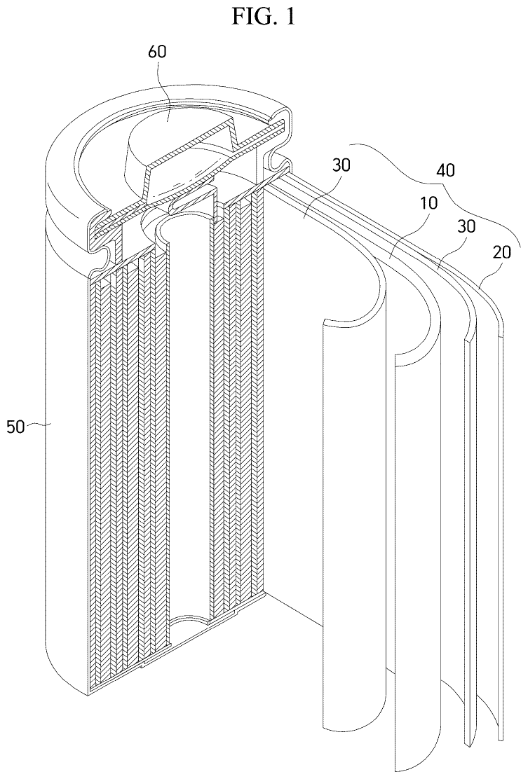

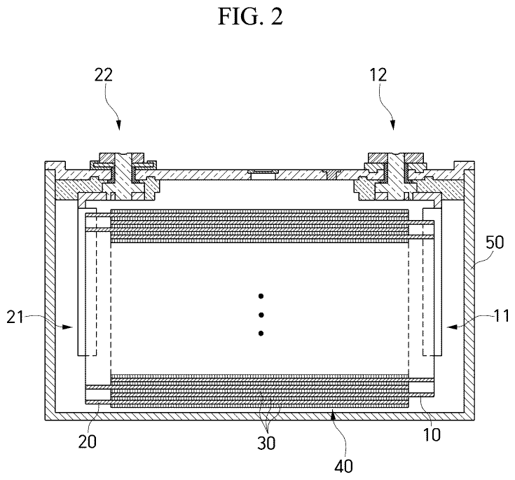

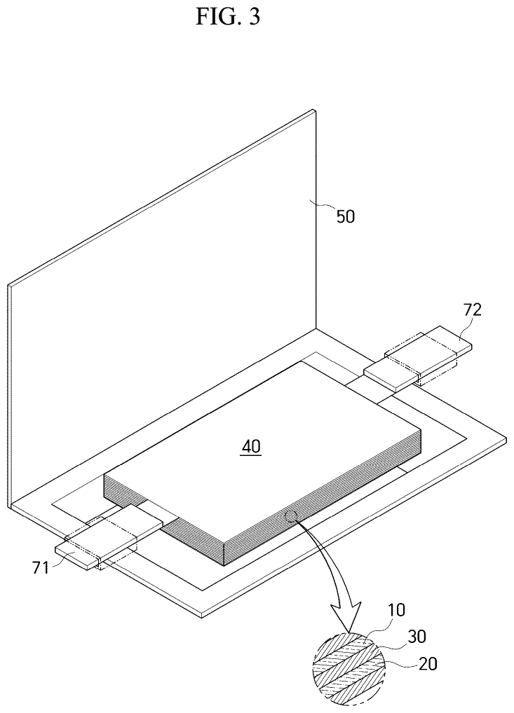

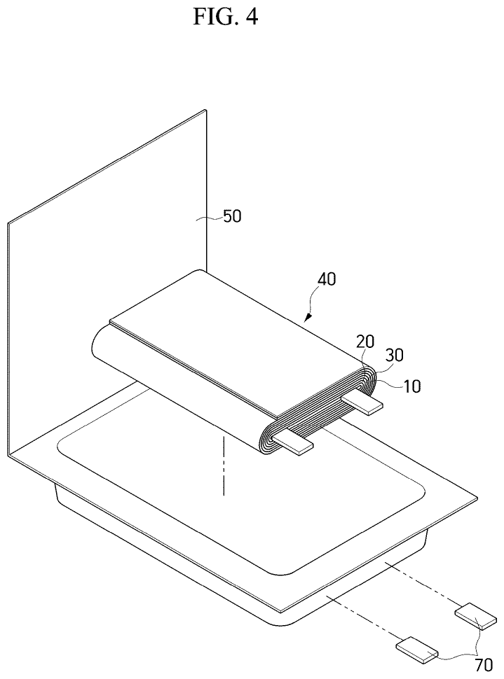

FIGS. 1 to 4 are schematic views illustrating lithium secondary batteries according to embodiments, wherein FIG. 1 shows a cylindrical type, FIG. 2 shows a prismatic type, and FIGS. 3 and 4 show pouch-type battery forms. Referring to FIGS. 1 to 4, a lithium secondary battery may include an electrode assembly (40) in which a separator (30) is interposed between a first electrode plate (10) and a second electrode plate (20), and a case (50) in which the electrode assembly (40) is accommodated. The first electrode plate (10), the second electrode plate (20), and the separator (30) may be impregnated with an electrolyte (not shown). As shown in FIG. 1, the lithium secondary battery may include a sealing member (60) for sealing the case (50). As shown in FIG. 2, the lithium secondary battery may include a first electrode lead tab (11) and a first electrode terminal (12), and a second electrode lead tab (21) and a second electrode terminal (22). As shown in FIGS. 3 and 4, the lithium secondary battery may include electrode tabs (70), that is, a first electrode tab (71) and a second electrode tab (72), which serve as electrical paths guiding current generated in the electrode assembly (40) to the outside.

The electrode assembly (40) may be formed by winding or stacking a laminate of a first electrode plate (10), a second electrode plate (20), and a separator (30), which are formed in a plate or film shape. When the electrode assembly (40) is a wound laminate, the winding axis may be parallel to the longitudinal direction of the case. The electrode assembly (40) may also be a stack type rather than a wound type, and the shape of the electrode assembly (40) is not limited in the present disclosure. The first electrode plate (10) of the electrode assembly (40) may serve as a positive electrode and the second electrode plate (20) may serve as a negative electrode, and vice versa.

The first electrode plate (10) may be formed by coating a first electrode active material, such as graphite or carbon, onto a first current collector formed of a metal foil such as copper, a copper alloy, nickel, or a nickel alloy, and may include a first electrode tab (or a first uncoated portion), which is a region to which the first electrode active material is not applied.

The second electrode plate (20) may be formed by coating a second electrode active material, such as a transition metal oxide, onto a substrate formed of a metal foil such as aluminum or an aluminum alloy, and may include a second electrode tab (or a second uncoated portion) (44), which is a region to which the second electrode active material is not applied.

The separator (30) functions to prevent a short circuit between the first electrode plate (10) and the second electrode plate (20) while allowing movement of lithium ions. The separator (30) may be formed of, for example, a polyethylene film, a polypropylene film, a polyethylene-polypropylene film, or the like.

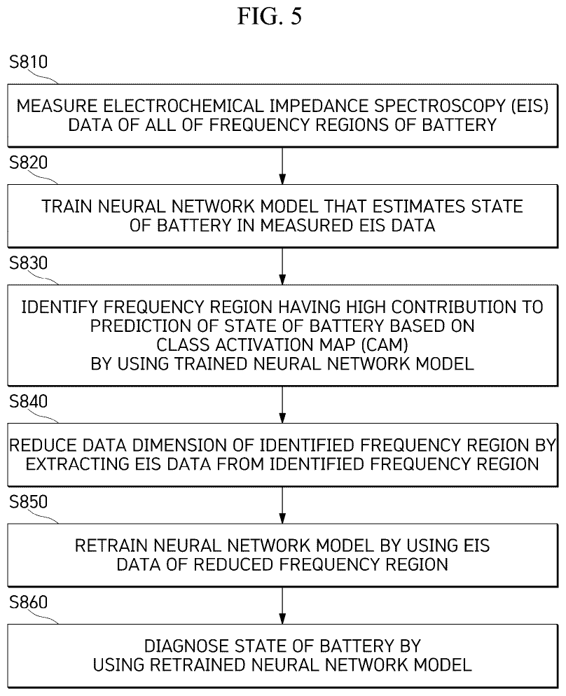

FIG. 5 is a diagram illustrating a method of diagnosing the state of a battery according to embodiments of the present disclosure.

As illustrated in FIG. 5, the method of diagnosing the state of a battery according to embodiments of the present disclosure is a method of diagnosing the state of a battery using an apparatus for diagnosing the state of a battery, and may include a step S810 of measuring electrochemical impedance spectroscopy (EIS) data of all of the frequency regions of a battery, a step S820 of training a neural network model that estimates the state of the battery in the measured EIS data, a step S830 of identifying a frequency region having a high contribution to the prediction of the state of the battery based on a class activation (CAM) by using the trained neural network model, a step S840 of reducing the data dimension of the identified frequency region by extracting EIS data from the identified frequency region, a step S850 of retraining the neural network model by using the EIS data of the reduced frequency region, and a step S860 of diagnosing the state of the battery by using the retrained neural network model.

Embodiments of the present disclosure relate to diagnosing the state of a battery. The state of the battery may be diagnosed by estimating the state of health (SOH) of the battery. The SOH of the battery is an index that quantitatively evaluates current performance and the aging state of the battery, and may be used to predict an available period and performance of the battery. Embodiments of the present disclosure may provide a method of diagnosing the state of a battery based on EIS data. The SOH of the battery may be evaluated based on data in a specific frequency region by using a neural network model.

First, the method of diagnosing the state of a battery according to embodiments of the present disclosure may include the step S810 of measuring the EIS data of all of the frequency regions of the battery.

The measurement of the EIS data may include measuring an impedance response of the battery according to a frequency change after an AC voltage or current is applied to the battery. In order to analyze internal resistance, a diffusion characteristic, and an interface reaction of a battery, data need to be obtained in a wide frequency region because electrochemical characteristics of the battery are different depending on the frequency.

The result of the measurement of the EIS data is indicated as an impedance value having a complex number form. In general, the result of the measurement of the EIS data is expressed in the form of a Nyquist plot (i.e., an imaginary number axis versus real number axis graph) and a Bode plot (i.e., a frequency versus phase and size graph). In embodiments of the present disclosure, data that are measured in the entire frequency range are used in a process of training a neural network model and extracting features. The measured data are used as data for predicting the SOH of a battery in a subsequent step.

The step S810 of measuring the EIS data according to embodiments of the present disclosure may include a step of generating impedance data having a complex number form by measuring impedance in the entire frequency range of the battery.

According to embodiments of the present disclosure, in order to analyze an electrochemical behavior of a battery, impedance may be measured in all of the frequency regions of the battery. The measurement of the EIS data may be performed in a way to record an impedance response according to a frequency change after a small AC signal is applied to the battery. In general, a frequency range used is in a 0.01 Hz to 100 KHz level, and may be adjusted depending on the capacity and characteristics of: the battery.

Impedance may be expressed as a complex number value. Accordingly, an electrochemical reaction within a battery may be quantitatively analyzed. In a high frequency region, information related to solid electrolyte interface (SEI) resistance of a battery may be provided. In a middle frequency region, ion conductivity and an interface reaction speed may be evaluated. In a low frequency region, a diffusion characteristic and intra-electrode reaction delay may be evaluated. In embodiments of the present disclosure, such data in the entire frequency range may be collected and used to evaluate the state of a battery and predict the SOH of the battery.

A method of measuring the EIS data of a battery may include a method of calculating impedance by measuring a responding current after an AC voltage (e.g., a small amplitude signal at a 5 mV level) is applied to a battery. The measured impedance data may be expressed in a form, such as the Nyquist plot (i.e., an imaginary number axis versus real number axis graph) or the Bode plot (i.e., a frequency versus phase and size graph). Accordingly, characteristics, such as internal resistance R, capacitance C, and inductance L of a battery, may be derived.

In embodiments of the present disclosure, impedance that is measured in all of the frequency bands of a battery may be stored by being converted into data having a complex number value. Impedance Z includes a real number part (resistance component) and an imaginary number part (reactance component), and may be expressed as follows.

Z(ω)=Z′(ω)+jZ″(∩)

In this case, Z′(ω) is a real number part of impedance and indicates a resistance (R) component within a battery. Z″(ω) is an imaginary number part of the impedance and indicates a component that is generated by a capacitance reaction and diffusion in an electrode/electrolyte interface. j denotes an imaginary unit (j2=−1j\hat{ }=−1j2=−1).

In embodiments of the present disclosure, after impedance data measured in a specific frequency region of a battery are collected, the impedance data may be stored as data having a complex number form and used to train a neural network model and predict the SOH of the battery. In a process of interpreting the EIS data of a battery, a phase angle 0 and a size |Z| may also be calculated. Such information functions to analyze an internal resistance increase of a battery, whether an electrode has been degraded, and the state of the battery, such as an ion diffusion speed reaction.

In embodiments of the present disclosure, a method of measuring and analyzing the EIS data of a battery may be applied to various battery types. For example, the SOH of a coin-shaped battery (45 mAh) may be evaluated by measuring 60 frequency points in a 0.02 Hz to 20 kHz range. The SOH of a cylindrical 18650 battery (NMC811) may be predicted by using 58 to 61 frequency points in a 0.01 Hz to 100 kHz range. An unbalanced state between cells within a battery pack for an electric vehicle (EV) may be detected by analyzing a specific impedance pattern having a high frequency band (10 kHz or more) and a low frequency band (0.01 Hz to 1 Hz).

An apparatus for measuring the EIS data of a battery may collect data in a frequency sweep manner. The measured data are used as an input for the training of a neural network model. In embodiments of the present disclosure, a CAM-based feature frequency point may be extracted and the state of a battery may be predicted more rapidly and accurately based on such data.

Accordingly, the method of diagnosing the state of a battery according to embodiments of the present disclosure is non-destructive and can rapidly diagnose the state of a battery, compared to the existing method of measuring capacitance by evaluating the SOH of a battery based on EIS data measured in the entire frequency range of the battery. In the existing method, the evaluation of the SOH requires repeated charge and discharge cycles, which is time-consuming and may adversely affect the actual service life of the battery. However, by employing the method according to embodiments of the present disclosure, the state of the battery can be evaluated within a matter of seconds, and changes in performance as well as the degradation state of the battery can be monitored in real time.

Furthermore, a reaction within the battery can be analyzed more precisely based on the impedance data having a complex number form. The prediction accuracy of the SOH of a battery can be improved by training a neural network model based on the fact that an impedance change in a specific frequency band has a direct relation with the SOH of the battery. Embodiments of the present disclosure may be designed to be capable of stably evaluating the SOH of a battery even in various environments (e.g., a temperature change and SOC), and may be used in various application fields, such as an electric vehicle, an energy storage device (ESS), and portable electronic devices.

Next, the method of diagnosing the state of a battery according to embodiments of the present disclosure may include the step S820 of training the neural network model that estimates the state of the battery in the measured EIS data.

In order to construct a model that predicts the state of a battery, a convolutional neural network (CNN)-based training structure may be adopted. An impedance value for each EIS frequency and the SOH data of a battery may be used as input data.

In a process of training a neural network model, a large amount of learning data is required in order to accurately predict the SOH of a battery. The EIS data of a battery in various SOC and temperature conditions may be required. Accordingly, a trained model may learn a correlation between the EIS pattern and SOH of a battery, and may evaluate an accurate state of the battery when receiving new battery data.

Furthermore, in the step of training the neural network model according to embodiments of the present disclosure, the state of the battery may be estimated by using the SOH of the battery data and the EIS data as an input.

In the method of diagnosing the state of a battery according to embodiments of the present disclosure, the step of training the neural network model is a process of training the neural network model so that the neural network model can predict the state of a battery by inputting the SOH data of the battery along with EIS data. Accordingly, the neural network model can accurately estimate the current state and performance of the battery by learning a relation between the electrochemical characteristics and SOH of the battery.

In the step S820 of training the neural network model by using the SOH data and EIS data of the battery according to embodiments of the present disclosure as an input, the SOH data of the battery may be set as a correct answer (or label), and the neural network model is trained by using the measured EIS data of the battery as an input value. The SOH is defined as the ratio of current capacitance to initial capacitance of the battery, and follows the following equation.

SOH=(current capacitance/initial capacitance)×100

The EIS data may include electrochemical information of the battery, and may incorporate an impedance feature in each frequency. In embodiments of the present disclosure, after EIS-measured data are collected in a complex number form in 0.01 Hz to 100 kHz range, a neural network model may be trained by converting the EIS-measured data into input data for the prediction of the SOH of a battery.

An input to the neural network model is impedance data measured in a specific frequency region of the battery, and an output from the neural network model is the SOH value of the battery. The EIS data that is used as an input value has the following structure.

X=[Z′(ω1), Z″(ω1), Z′(ω2), Z″(ω2), . . . , Z′(ωn), Z″(ωn)]

In this case, Z′(ω) and Z″(ω) refer to real number and imaginary number components in each frequency w, respectively. In embodiments of the present disclosure, a neural network model that estimates the SOH of a battery may be trained by converting such data into an input to the neural network model.

In embodiments of the present disclosure, for the training of a neural network model, a convolutional neural network (CNN) may be used. The CNN model may perform a role of learning a relation between input EIS data and the SOH of a battery by processing the EIS data.

In a process of training the neural network model, first, the EIS data having a complex number form may be converted into a real number value so that the EIS data are arranged in an input form of the neural network model. The neural network model may automatically learn features that are important in the EIS data by using the convolution layer of the CNN. Furthermore, a fully connected (FC) layer that predicts the SOH of the battery may be finally trained by receiving extracted features as an input. Furthermore, a loss may be calculated by comparing a predicted SOH value and an actual SOH value. The neural network model may be optimized through back-propagation.

In embodiments of the present disclosure, when the neural network model is trained, a mean absolute percentage error (MAPE) is used as a loss function and defined as follows.

MAPE=1/n Σ|(SOH_{actual,I}−SOH_{predicted,i})/SOH_{actual,i}|×100 (i=1~n)

Accordingly, the training may be performed so that a difference between an SOH value predicted by the neural network model and an actual SOH value is minimized.

In embodiments of the present disclosure, the neural network model may be trained with respect to various types of batteries.

In a coin-shaped battery (45 mAh), EIS data measured in different temperature conditions, such as 25 °C, 35 °C, and 45 °C, may be used as learning data by using 7; batteries.

In the case of a cylindrical battery (NMC811), the neural network model may be trained based on experiment data of cells collected from six organizations.

In the case of a battery pack for an electric vehicle (EV), the neural network model may be trained by using EIS data of individual cells within a battery pack as learning data.

Data that are used as an input to the neural network model may be normalized and used depending on the charging and discharging state (SOC), temperature, and use history of each battery, and may be formed so that the SOH of each battery can be stably predicted even in various environments.

Accordingly, according to embodiments of the present disclosure, a neural network model for predicting the SOH of a battery may be trained. Accordingly, it is possible to evaluate the state of the battery in real time and to predict precise SOH of the battery by considering electrochemical characteristics. In the existing method, the SOH of a battery is measured through charging and discharging experiments for the battery. However, according to embodiments of the present disclosure, it is possible to diagnose the state of a battery based on EIS data non-destructively and rapidly.

Furthermore, the influence of a temperature change, SOC condition, and aging degree of a battery can be reflected and the prediction accuracy of the SOH of a battery can be improved, by training a neural network model based on a CNN. Accordingly, embodiments of the present disclosure may be used in various application fields, such as an electric vehicle, an energy storage system (ESS), and a smart battery management system (BMS).

The step S820 of training the neural network model according to embodiments of the present disclosure may include a step of normalizing input data of the neural network model by reflecting the state of charge (SOC) and temperature condition of the battery. In this case, relation between electrochemical characteristics and SOH of the battery can be reflected more accurately. The neural network model can perform a role of maintaining stable performance even in various operation environments.

Electrochemical impedance spectroscopy (EIS) data of a battery are different depending on the SOC and temperature condition of the battery at the time of the measurement of the EIS data. In embodiments of the present disclosure, input data for a neural network model is standardized (or normalized) so that an influence according to a change in the SOC and temperature condition is not distorted in a neural network training process.

In this process, first, an SOC range may be divided into some intervals and a distribution of measured EIS data may be normalized for each interval, because the measured EIS data are different for each SOC interval depending on the SOC of a battery. Furthermore, a temperature change of the battery may be normalized by considering the variability of an impedance value according to a temperature change because the temperature change has a great influence, in particular, in a low frequency region (e.g., 0.01 Hz to 1 Hz) of the EIS data.

In embodiments of the present disclosure, a method of calculating and normalizing the mean (u) and standard variance (o) of data (conversion into a standard score and Z-score normalization) may be used and defined as the following equation.

X_{normalized}=(X−μ)/σ

In this case, X is original data. μ is an average impedance value in a specific SOC and temperature condition. σ is a standard variance in a specific soc and temperature condition.

Furthermore, after frequency points having a high contribution to the prediction of the SOH are selected based on a class activation map (CAM), an impedance value on a corresponding frequency may be normalized depending on an SOC and temperature condition. In order to minimize the influence of a change in the SOC of a battery on EIS data, a normalization reference is set based on multiple datasets measured in the same battery type.

In embodiments of the present disclosure, when a neural network model is trained, normalized input data may be used so that the neural network model is not overfitted with respect to a change in the SOC and temperature condition.

In this case, learning datasets may be clustered for each SOC and temperature condition so that a distribution of data is balanced when the neural network model is trained. Data measured in a specific SOC range (e.g., 10% to 20% or 20% to 30%) and a specific temperature range (e.g., 25 °C, 35 °C, or 45 °C) may be grouped so that a neural network model is not biased to only a specific condition.

Furthermore, a neural network model may be trained to learn a relation between the EIS data and SOH of a battery by using data that are normalized for each SOC and temperature condition as an input. In order to estimate accurate SOH in various operation environments of a battery, input data for the neural network model should not be distorted in a specific condition.

Furthermore, in order to correct a change in the impedance value according to a temperature change, a correction factor according to the temperature change (i.e., a temperature correction factor) may be applied. In embodiments of the present disclosure, the temperature correction factor may be incorporated into a process of normalizing input data for a neural network model so that predicted performance of the neural network model is maintained in a predetermined temperature range.

In embodiments of the present disclosure, normalization into which the SOC and temperature condition for a battery have been incorporated may be performed by using EIS data measured in various battery types.

In the case of a coin-shaped battery (45 mAh), a neural network model may be trained by using EIS data measured in different temperature conditions, such as 25 °C, 35 °C, and 45 °C. Normalization for each SOC condition may be applied. In the case of a cylindrical battery (NMC811), data may be normalized in a 10% unit in an SOC range of 10% to 100%. A neural network model may be trained by reflecting a temperature change (e.g., 23 °C or 45 °C). In the case of a battery pack for an electric vehicle (EV), data may be normalized on the basis of an SOC and temperature condition for an individual cell within the battery pack, and may be used to predict the SOH of the entire pack.

As described herein, according to embodiments of the present disclosure, the SOH of a battery can be accurately predicted even in various environments by normalizing input data for a neural network model based on an soc and temperature condition. The variability of EIS data according to an SOC change and a temperature difference may be normalized so that a neural network model can be prevented from being overfitted for a specific condition. It is possible to maintain consistent prediction performance of the SOH.

Furthermore, it is possible to reliably diagnose the state of a battery in various application fields, such as an electric vehicle (EV), an energy storage system (ESS), and a battery management system (BMS) by minimizing the influence of a temperature change and an SOC condition.

Next, the method of diagnosing the state of a battery according to embodiments of the present disclosure may include the step S830 of identifying a frequency region having a high contribution to the prediction of the state of a battery based on a class activation map (CAM) by using the trained neural network model.

A frequency region having a high contribution to the prediction of the SOH of a battery may be identified by applying a CAM scheme by using the trained neural network model. The CAM is a technique in which input data that play an important role in a process of a neural network model predicting the SOH of a battery are visualized. Accordingly, whether a specific frequency region makes a decisive contribution to the evaluation of the state of a battery may be analyzed.

Results obtained through analysis based on the CAM may be used to reduce a frequency region that needs to be measured while maintaining the prediction accuracy of the SOH. A measuring time can be significantly reduced by selecting an optimized frequency region. In the existing method, all of frequency bands have to be measured. However, in embodiments of the present disclosure, efficiency can be maximized because only major frequency bands are selectively measured.

According to embodiments of the present disclosure, the step S830 of identifying the frequency region based on the CAM may include a step of selecting a frequency point having a high contribution to the prediction of the SOH of a battery through analysis based on a CAM score of the trained neural network model.

In the method of diagnosing the state of a battery according to embodiments of the present disclosure, the step of identifying the frequency region based on the CAM may be a process of automatically selecting a frequency point having a high contribution to the prediction of the SOH of a battery by using the learnt weight of a neural network model. Accordingly, major features may be selected in impedance data of a battery, and prediction performance of the SOH can be maintained while reducing the data dimension of the frequency region.

Electrochemical impedance data of a battery may be measured in multiple frequency regions. A specific frequency band may have a greater influence on the prediction of the SOH of a battery. In embodiments of the present disclosure, a neural network model may perform a process of automatically selecting a frequency point that is important for the prediction of the SOH by using a class activation map (CAM) score.

First, after the SOH is predicted by using the neural network model, a frequency region having a high contribution to the prediction of the SOH may be identified by using a CAM. A CAM score may be derived from the last convolution layer of the neural network model. The CAM score may be calculated in a way to emphasize a frequency point having the highest correlation with the prediction of the SOH.

The CAM score may be defined as the following equation.

S_{CAM}(f)=ΣwᵢAᵢ(f)

In this case, S_{CAM}(f) is a CAM score in a specific frequency f. wᵢ is a neural network weight for the prediction of final SOH. Aᵢ(f) is a value of an activation map in the specific frequency f.

Furthermore, a frequency region having the greatest influence on the prediction of the SOH may be filtered by selecting only a frequency point having a CAM score greater than a specific threshold. In embodiments of the present disclosure, an unnecessary frequency may be removed from all of data and calculation efficiency may be improved by selecting upper 5 or 10 frequency points having high CAM scores.

For example, upper 5 frequencies (e.g., 0.1 Hz, 1 Hz, 10 Hz, 100 Hz, and 1 kHz), among all of 60 frequency points, may be selected through CAM-based analysis.

Furthermore, the training of a neural network model may be optimized by reconstructing input data for the neural network model by using the selected frequency points and reducing the data dimension of a frequency region. It is possible to reduce a computational load and to maintain the prediction accuracy of the SOH, compared to a case in which all of pieces of frequency information of EIS data are used in a conventional technology.

As detailed embodiments, frequency selection based on a CAM may be performed by using EIS data measured in various battery types.

In the case of coin-shaped battery (45 mAh), frequency points that are important for the prediction of the SOH of the battery may be extracted by performing CAM analysis on data measured at 25 °C, 35 °C, and 45 °C. As a result of experiments, a mean absolute percentage error (MAPE) was maintained at 2. 77% or less by using only 5 core frequencies, among 60 frequencies.

In the case of a cylindrical battery (NMC811), data measured in all of frequency bands (e.g., 0.02 Hz to 20 kHz) may be filtered through CAM analysis. The prediction of the SOH of the battery may be performed by selecting core frequency points. A calculation time reduction effect of about 1100 times compared to the existing method was checked.

Accordingly, according to embodiments of the present disclosure, it is possible to significantly reduce a computational load and also maintain the prediction accuracy of the SOH of a battery, compared to the existing method based on all of EIS data, because a neural network model automatically selects frequency points having a high contribution to the prediction of the SOH.

Furthermore, the neural network model may be trained to learn only essential frequency information so that the neural network model is not overfitted for a specific frequency in order to improve generalization performance of the neural network model for a state of charge (SOC) change and a temperature condition change. accordingly, the state of a battery can be reliably diagnosed in various application fields, such as an electric vehicle (EV), an energy storage system ESS), and a battery management system (BMS).

According to embodiments of the present disclosure, the step S830 of identifying the frequency region based on the CAM may include a step of selecting frequency points on which the SOH of a battery can be reliably predicted even in a specific SOC condition by reflecting an impedance feature according to a change in the SOC of the battery.

That is, it is important to select a frequency point that is robust against SOC variability without simply selecting a frequency point having a high CAM score because internal resistance and reactivity of the battery are different depending on an SOC change.

First, in order to accurately estimate the SOH of the battery, an impedance change characteristic according to an SOC state may need to be incorporated. In embodiments of the present disclosure, a method of selecting a frequency point that has a consistent influence according to the SOC change by using a CAM score of a neural network model may be applied.

First, internal reactivity of a battery may be changed as the Soc of the battery is increased or decreased. An impedance change of the battery is changed in a specific frequency band.

For example, in the state in which the SOC is 20%, the impedance change may be great in a specific low frequency region (e.g., 0.1 Hz to 1 Hz). In the state in which the SOC is 80%, the impedance change may be significant in a high frequency region (e.g., 1 khz to 10 kHz). In order to incorporate a difference between the types of SOC, impedance data of a battery may be measured and analyzed in various SOC conditions, and a frequency point capable of correcting an influence according to the SOC change may be selected.

Furthermore, after a neural network model is trained, a frequency point that plays the most important role in the prediction of the SOH may be analyzed by using a CAM score. In this case, a frequency point having a high CAM score should not be simply selected, but a frequency point that has a relatively stable influence according to the SOC change needs to be selected.

For example, when specific frequencies f₁, f₂, and f₃ have high CAM scores in the SOC of 20%, but the CAM scores of the specific frequencies are suddenly changed in the SOC of 80%, the specific frequencies may have low reliability in the prediction of the SOH. Accordingly, a process of selecting a frequency point that has a stable influence in all of SOC conditions may be performed.

Furthermore, a frequency point having a high CAM score only in specific SOC may be excluded and a frequency point having a consistent contribution even in various Soc conditions may be selected so that the prediction of the SOH can be reliably performed even in a specific SOC condition.

To this end, a distribution of CAM scores according to an SOC change may be analyzed for each frequency point, and a frequency having a low variance according to the SOC change may be preferentially selected.

For example, when specific frequency points f₄ and f₅ have a stable influence in an SOC range of 20% to 80%, it is more reliable to use corresponding frequencies in the prediction of the SOH of a battery.

Finally, the prediction accuracy of the SOH can be improved by constructing input data for a neural network model by using selected frequency points and applying correction function to an Soc change. A frequency selection method to which SOC corrections have been applied is not optimized for only a specific SOC condition, and can support the prediction of the SOH that is consistent in the entire SOC range.

As detailed embodiments, a frequency point that is robust against an SOC change may be selected by using impedance data of a battery measured in various soc conditions.

In the case of a 45 mAh coin-shaped battery, a frequency having a high contribution to the prediction of the SOH of the battery may be identified by measuring the EIS data of the battery in the SOC of 20%, 50%, and 80% and performing CAM analysis. Specific frequencies f₁=0.1 Hz, f₂=1 Hz, and f₃=100 Hz had high CAM scores in the SOC of 50%, but had low contributions in the SOC of 20% and the SOC of 80%. The reliability of the prediction of the SOH can be improved by finally selecting the frequencies f₄=10Hz and f₅=1 kHz having stable CAM scores regardless of the SOC change.

In the case of a cylindrical battery, the EIS data of the battery were measured in the SOC range of 10% to 90%, and a change in the frequency points for each SOC was compared and analyzed. The reliability of the prediction of the SOH of the battery can be improved by selecting a frequency having a low variance in the CAM score for each SOC. A frequency point that is finally selected is applied by performing SOC corrections through an SOH prediction model.

Accordingly, according to embodiments of the present disclosure, in a process of selecting a frequency point based on a CAM, the prediction of performance of the SOH of a battery can be consistently maintained even in a specific SOC condition by considering reliability according to an SOC change.

Furthermore, the reliability of the prediction of the SOH can be improved and a prediction error according to a change in the SOC of a battery can be minimized, by removing a frequency point having a great variance for each SOC. Accordingly, the accuracy and consistency of the diagnosis of the state of a battery can be maintained in various application environments, such as an electric vehicle (EV), an energy storage system (ESS), and a battery management system (BMS).

Next, the method of diagnosing the state of a battery according to embodiments of the present disclosure may include the step S840 of reducing the data dimension of the frequency region by selecting the EIS data of the battery in the identified frequency region.

The dimension of input data for a neural network model may be reduced by selecting the EIS data of a battery in major frequency regions identified through CAM-based analysis. In the existing method, data measured at 60 or more frequency points are used. In contrast, in embodiments of the present disclosure, a small number of frequency points (e.g., 5) having a high contribution may be selected and used for training and prediction.

A reduction of the data dimension is a process of removing unnecessary frequency information and leaving only core features, and has effects in that a computational load of a neural network model is reduced and the training speed is improved. Furthermore, a reduction of data enables real-time analysis in a process of predicting the SOH of an actual battery and can guarantee high efficiency in large-Attorney scale evaluation in a battery pack unit.

The step S840 of reducing the data dimension of the frequency region by selecting EIS data in an identified frequency region according to embodiments of the present disclosure may include a step of removing unnecessary data in an identified frequency region and reducing the dimension of data by using only selected frequency points. The step may be a process of removing unnecessary data and reducing the size of input data by using only selected frequency points so that a neural network model can predict the SOH of a battery more accurately. The existing EIS data are measured in a wide frequency range. However, if only some frequency points having a substantially high contribution to the estimation of the SOH are used, a computational load can be reduced and the accuracy of the SOH may be maintained.

EIS data are an important factor in incorporating electrochemical characteristics of a battery, but all of frequency points do not have the same contribution to the estimation of the SOH. In embodiments of the present disclosure, a method of identifying frequency points having a high contribution to the prediction of the SOH of a battery based on a CAM after a neural network model is trained and reducing the data dimension of a frequency region by using only the frequency points may be applied.

First, the existing EIS data include several tens or several hundreds of frequency points. If all of the several tens or several hundreds of frequency points are used as an input to a neural network model, a computational load of the neural network model is increased. If frequency data that are not substantially necessary for the estimation of the SOH fa battery are removed, an operation speed can be increased and a model training time can be reduced.

Furthermore, if unnecessary frequency data are included, there is a good possibility that a neural network model may learn a pattern not related to actual SOH of a battery. If only a frequency point having a high contribution to the prediction of the SOH of a battery is selected, a neural network model can estimate the state of the battery more accurately.

Furthermore, if only a selected frequency point is used, the time that is taken to measure EIS data of an actual battery can be reduced. In the existing method, several tens of seconds to several hundreds of seconds may be taken to measure the entire frequency range. In contrast, the present method can improve a measurement speed because only a required frequency point has only to be measured.

First, impedance of a battery for the entire frequency range (e.g., 0.02 Hz to 20 kHz) may be measured. Impedance data having a complex number form may be generated. The measured data may be expressed as a complex number component (i.e., a real number part and an imaginary number part). Electrochemical characteristics of a battery according to a frequency may be incorporated into the data.

Furthermore, a trained neural network model may select a frequency point having a high contribution to the prediction of the SOH of the battery by analyzing a CAM score. For example, 5 to 7 core frequency points, among all of 60 frequency points, may have the most important influence on the prediction of the SOH.

Furthermore, a frequency having a low contribution may be removed from an identified frequency region, and only a selected frequency point may be left

For example, if originally measured frequency points are f₁, f₂, f₃, . . . , f₆₀, only core frequency points f₁₀, f₂₅, f₃₇, f₄₅, and f₅₂ selected through CAM analysis may be maintained and the remainder may be removed. The neural network model may be trained to perform the prediction of the SOH by using only the selected frequency points. Data having a dimension reduced may have a small computational load and also maintain the accuracy of the SOH compared to a case in which all of frequency data are used conventionally.

Specifically, as a result of the execution of experiments for a 45 mAh coin-type cell and a cylindrical cell, it was found that operation efficiency could be maximized and the prediction accuracy of the SOH can be maintained through a reduction of a data dimension.

As a result of the experiments for the 45 mAh coin-type cell, when all of frequency points (e.g., 60) were used, a mean absolute percentage error (MAPE) was 1.23% and a measuring time was 239.545 seconds. When only 5 frequency points were selected based on the CAM, an MAPE was 2.77%, and a measuring time was 0.599 second. The measuring time was reduced approximately 400 times compared to the existing neural network model.

As a result of the experiments for a cylindrical cell, when all of frequency points (e.g., 60) were used, an MAPE was 1.22% and a measuring time was 299.996 seconds. When only 5 frequency points were selected based on the CAM, an MAPE was 1.80%, and a measuring time was 0.027 second. The measuring time was reduced approximately 11000 times compared to the existing neural network model.

Although all of frequency data are used, such results of the experiments may mean that the time taken to measure EIS data and a computational load can be significantly reduced while maintaining the prediction accuracy of the SOH of a battery at a predetermined level.

As described herein, according to embodiments of the present disclosure, the training speed of a neural network model for predicting the SOH of a battery can be improved by removing unnecessary data in an identified frequency region and reducing the data dimension of the frequency region by using only selected frequency points. Furthermore, the overfitting of the neural network model can be prevented and generalized performance of the neural network model can be improved because unnecessary data are removed. Moreover, real-time performance in the diagnosis of the state of a battery can be increased by significantly reducing the time taken to measure EIS data. The SOH of a battery can be predicted rapidly and accurately in various application environments, such as an electric vehicle (EV), an energy storage system (ESS), and a battery management system (BMS).

Next, the method of diagnosing the state of a battery according to embodiments of the present disclosure may include the step S850 of retraining the neural network model based on the EIS data of the reduced frequency region.

An original neural network model is trained by using all of frequency data, but additional model optimization may be performed by using changed datasets after a data dimension is reduced.

A retraining process may be performed in a way that a model learns a new weight optimized for reduced data while maintaining the weight of the existing neural network model. Accordingly, a computational load can be reduced compared to the existing neural network model, and the prediction accuracy of the SOH of a battery can be maintained. Furthermore, a retrained neural network model can rapidly evaluate the state of the battery based on only given major frequency points.

That is, in the method of diagnosing the state of a battery according to embodiments of the present disclosure, the step of retraining the neural network model based on the EIS data of the reduced frequency region may be a process of retraining the neural network model based on selected frequency points after a data dimension is reduced and verifying prediction performance of the SOH of a battery.

In embodiments of the present disclosure, all of frequency regions are not used, and the data dimension of a frequency region is reduced by selecting only some frequency points having a high contribution to the prediction of the SOH of a battery based on a class activation map (CAM). However, the existing neural network model is in the state in which the existing neural network model has learnt all of original frequency data. Accordingly, if dimension-reduced data are directly input to the existing neural network model, there is a possibility that prediction performance of the SOH may be degraded. In order to prevent the possibility, in embodiments Of the present disclosure, the step of retraining the neural network model based on reduced datasets may be added.

If only reduced frequency data are used, performance of the SOH may be degraded because an originally trained neural network model has been optimized based on all of frequency data. Accordingly, if the neural network model is retrained based on reduced datasets, the existing performance can be maintained or improved based on only selected frequency points.

Furthermore, if the neural network model is retrained in the state in which unnecessary frequency data have been removed, the overfitting possibility is reduced because the neural network model learns only core information for the prediction of the SOH. Through the retraining, the SOH of a battery can be reliably predicted even in various state-of-charge (SOC) and temperature conditions. Through the retraining of the neural network model, a computational load can be reduced while maintaining prediction performance of the SOH. When only reduced frequency points are used, the neural network model can operate lightly and rapidly compared to the existing neural network model.

According to embodiments of the present disclosure, a detailed process of retraining a neural network model first includes selecting a frequency point having a high contribution to the prediction of the SOH of a battery through CAM-based analysis. A dataset having a reduced dimension may be generated by maintaining only frequency points selected in all of existing EIS data and removing unnecessary data.

Furthermore, the neural network model is trained again by using the dataset having a reduced dimension based on the existing trained neural network model. A convolution layer of a convolutional neural network (CNN)-based model may use selected frequency points as an input and secures training stability by applying batch normalization and dropout schemes. A training process may be adjusted so that the same prediction performance of the SOH of a battery can be maintained although only reduced data are used compared to the existing neural network model.

Furthermore, the prediction performance of the SOH may be evaluated by using the retrained neural network model. Performance of the existing neural network model and performance of the retrained neural network model may be compared. Prediction accuracy may be analyzed based on evaluation indices, such as a mean absolute percentage error (MAPE), a root mean square error (RMSE), and R² (a coefficient of determination). Whether prediction performance of the SOH that is equal to or greater than a predetermined level is maintained even after a data dimension is reduced is checked.

As detailed embodiments, as a result of the execution of experiments for a 45 mAh coin-type cell and a cylindrical cell, it was checked that the process of retraining the neural network model plays an important role in maintaining prediction performance of the SOH.

As the result of the experiments of the 45 mAh coin-type cell, when all of the frequency points 60 were used, an MAPE was 1.23% and a measuring time was 239.545 seconds. When five frequency points were selected based on the CAM, an MAPE was 4.25% (before retraining). If five frequency points were selected based on the CAM, when a neural network model was retrained, an MAPE was 2.77% and a measuring time was 20.599 seconds. The measuring time could be reduced approximately 11 times.

As the result of the experiments for the cylindrical cell, when all of the frequency points 60 were used, an MAPE was 1.22% and a measuring time was 299. 996 seconds. When five frequency points were selected based on the CAM, an MAPE was 3.80% (before retraining). If five frequency points were selected based on the CAM, when the neural network model was retrained, an MAPE was 1.80% and a measuring time was 0.027 second. The measuring time could be reduced approximately 1100 times.

Such results of the experiments show that the prediction accuracy of the SOH may be reduced if the retraining process is not performed and prediction accuracy may be recovered to a level similar to the existing performance if the neural network model is retrained by using only the selected frequency points.

According to embodiments of the present disclosure, prediction performance of the SOH of a battery can be maintained even after a data dimension is reduced by retraining a neural network model by using the EIS data of a reduced frequency region. Furthermore, the overfitting of the neural network model can be prevented through the retraining of the neural network model. Generalized performance can be improved so that the SOH of the battery can be reliably predicted even in various battery SOC and temperature conditions. Moreover, if a reduced dataset is used, real-time performance of the diagnosis of the state of the battery can be improved because a computational load of the neural network model is reduced. The SOH of the battery can be predicted rapidly and accurately in various application environments, such as an electric vehicle (EV), an energy storage system (ESS), and a battery management system (BMS).

In the step S850 of retraining the neural network model according to embodiments of the present disclosure, the retraining of the neural network model may be performed in a way to minimize an error of the prediction of the SOH by comparing and evaluating performance of the existing neural network model and the neural network model using the reduced dataset. The step S850 of retraining the neural network model may be a process of optimizing the neural network model so that prediction performance of the SOH is not degraded after the data dimension is reduced.

In embodiments of the present disclosure, after a neural network model is trained based on the EIS data of the entire frequency range, only some frequency points having a high contribution to the prediction of the SOH of a battery may be selected through CAM-based analysis and the data dimension of a frequency region may be reduced. However, there is a need for a process of comparing and evaluating the neural network model according to embodiments of the present disclosure and the existing neural network model after the retraining the neural network model because a difference between performance of the neural network model and performance of the existing neural network model may occur when the data dimension is reduced.

The prediction accuracy of the SOH using the existing neural network model and the prediction accuracy of the SOH using a retrained neural network model using a reduced dataset are compared so that the retrained neural network model can maintain performance of the existing neural network model or performance of the retrained neural network model can be improved. Prediction performance of the retrained neural network model may be evaluated based on indices, such as S a mean absolute percentage error (MAPE), a root mean square error (RMSE), and a coefficient of determination (R²). The training of the neural network model may be adjusted in a way to minimize an error of the SOH.

Furthermore, it is checked whether the neural network model using the reduced dataset maintains performance equivalent to that of the existing neural network model. The influence of a reduction in the data dimension on performance of the retrained neural network model may be analyzed by comparing the prediction accuracy of the SOH using the existing neural network model based on all of frequency data and the prediction accuracy of the SOH using the retrained neural network model using only specific frequency points.

Furthermore, performance of the neural network model may be evaluated and adjusted so that the SOH using the neural network model can be stably predicted even in various experiment environments, such as SOC and a temperature condition. A problem in that performance is degraded in a specific condition may be prevented by comparing the existing neural network model and the retrained neural network model.

The comparison and evaluation of performance of a neural network model according to embodiments of the present disclosure may include the following steps.

First, the prediction of the SOH of a battery may be performed by using the existing neural network model trained by using all of frequency data in order to measure prediction performance of the SOH using the existing neural network model. Performance the existing neural network model may be set as a reference value, and evaluation indices (e.g., MAPE, RMSE, and R²) may be calculated and recorded.

Furthermore, a neural network model may be retrained by using a dataset in which only frequency points having a high contribution to the prediction Of the SOH are maintained through a CAM-based frequency selection process. Training stability may be secured by applying a batch normalization and dropout scheme, and the neural network model is adjusted to be not overfitted for specific data.

Furthermore, the result of the prediction of the SOH using the existing neural network model and the result of the prediction of the SOH using the retrained neural network model are compared by applying the same test data. Whether the retrained neural network model maintains the same prediction performance as the existing neural network model without the degradation of the performance may be checked by analyzing an error of the prediction of the SOH (or MAPE or RMSE). Furthermore, whether the neural network model has consistent performance even in a change in the SOC change or temperature condition may be verified.

Furthermore, the retrained neural network model may be adjusted in a way to minimize an error of the prediction of the SOH. An optimized model may be selected. A neural network model having a reduced computational load while maintaining prediction performance of the SOH compared to the existing neural network model may be finally applied.

According to detailed embodiments, as a result of the execution of experiments for a 45 mAh coin-type cell and a cylindrical cell 18650, it was found that an error of the prediction of the SOH of a battery using a neural network model using a reduced dataset can be minimized after performance of the existing neural network model and performance of the neural network model using a reduced dataset were compared and evaluated.

As the result of the experiments for the 45 mAh coin-type cell, in the case of the existing neural network model (i.e., all of frequencies are used), an MAPE was 1.23% and a measuring time was 239.545 seconds. In contrast, in the case of the neural network model (before retraining) using a reduced dataset, an MAPE was 4.25%. In the case of the neural network model (after retraining) using a reduced dataset, an MAPE was 2.77% and a measuring time was 0.599 second. The measuring time was reduced approximately 400 times.

As the result of the experiments for the cylindrical cell, in the case of the existing neural network model (i.e., all of frequencies are used), an MAPE was 1.22% and a measuring time was 299.996 seconds. In contrast, in the case of the neural network model (before retraining) using a reduced dataset, an MAPE was 3.80%. In the case of the neural network model (after retraining) using a reduced dataset, an MAPE was 1.80% and a measuring time was 0.027 second. The measuring time was reduced approximately 11000 times.

Accordingly, according to embodiments of the present disclosure, an error of the prediction of the SOH of a battery can be minimized by comparing and evaluating performance of the existing neural network model and performance of the neural network model using a reduced dataset. Furthermore, a computational load can be reduced and real-time performance of the diagnosis of the state of the battery can be improved by retraining a neural network model so that prediction performance of the SOH can be maintained even after a data dimension is reduced through the comparison and evaluation of performance.

Next, the method of diagnosing the state of a battery according to embodiments of the present disclosure may include the step S860 of diagnosing the state of the battery by using the retrained neural network model.

That is, the state of an actual battery is diagnosed by using the retrained neural network model. In the diagnosis process, the SOH of the battery may be predicted by using the EIS data of a reduced frequency region as an input. A predicted SOH value of the battery may be used to analyze the degradation state of the battery and to predict the lifespan of the battery.

Furthermore, a change in internal resistance of the battery and the degree of the degradation of an electrode may be evaluated based on the result of the diagnosis. The result of the diagnosis may be applied as a criterion on which whether a battery can be used is determined. When the SOH of the battery is less than a specific threshold, it is necessary to replace or reuse the battery. Maintenance and repair and operation efficiency of the battery can be improved by providing such information in real time.

According to embodiments of the present disclosure, the step S860 of diagnosing the state of the battery by using the retrained neural network model may include a step of predicting the SOH of the battery by receiving the EIS data of a reduced frequency region as an input and analyzing the degradation state of the battery based on the predicted SOH.

The SOH of the battery is an index indicative of the remaining lifespan and performance of a battery. In the method according to embodiments of the present disclosure, the SOH of a battery may be quantitatively predicted by using a retrained neural network model. The degradation state of the battery may be analyzed based on the predicted SOH.

Unlike in the existing method using all of frequency data, in embodiments of the present disclosure, the SOH of a battery may be predicted by using some frequency points selected based on the CAM. Accordingly, there is a need for an analysis process that is optimized so that a neural network model can predict the SOH by using the data of a reduced frequency region as an input. The result of the prediction of the SOH is not used as a simple state index, but may be used to analyze the degradation mechanism of the battery. The state of the battery may be evaluated by considering various factors, such as a change in internal resistance of the battery, a reduction in the charging and discharging cycle, and damage to an electrode.

In embodiments of the present disclosure, a process of diagnosing the state of a battery may include the following steps.

First, major frequency points selected through CAM-based analysis in EIS data may be used as an input to a neural network model. The SOH of a battery may be predicted by using only selected feature frequency data without using all of frequency data as an input as in the existing method.

Furthermore, the SOH of the battery may be estimated by using the neural network model. An output layer of the neural network model may calculate an SOH value as a continuous value by applying an active function (e.g., a linear regression operation). The neural network model may be optimized in a way to minimize an error of the prediction of the SOH by comparing performance of the existing neural network model and performance of the retrained neural network model.

Furthermore, the degradation state of the battery may be analyzed based on a predicted SOH value. When the SOH value falls below a predetermined threshold, the possibility that internal resistance of the battery is increased and an electrode is degraded may be diagnosed. A battery degradation tendency according to charging and discharging cycles may be derived and a battery replacement time may be predicted, by analyzing an SOH change pattern.

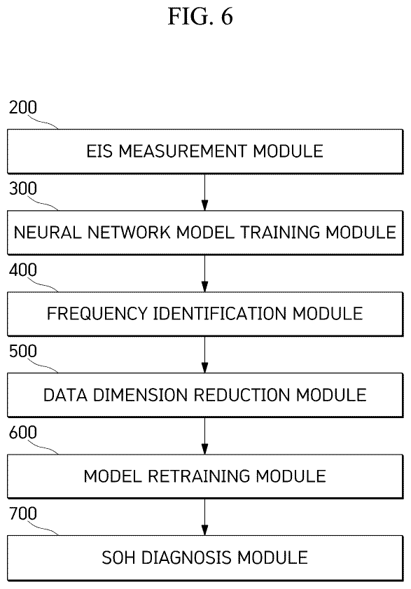

FIG. 6 is a diagram illustrating an apparatus for diagnosing the state of a battery according to embodiments of the present disclosure. A detailed description of some components that are redundant with those according to the embodiments of the apparatus for diagnosing the state of a battery may be omitted or described in brief in embodiments.

The apparatus for diagnosing the state of a battery according to embodiments of the present disclosure may include an electrochemical impedance spectroscopy (EIS) measurement module 200 that measures the EIS data of all of the frequency regions of a battery, a neural network model training module 300 that trains a neural network model for estimating the state of the battery based on the measured EIS data, a frequency identification module 400 that identifies a frequency region having a high contribution to the prediction of the state of the battery based on a class activation map (CAM) by using the trained neural network model, a data dimension reduction module 500 that selects EIS data in the identified frequency region and reduces the data dimension of the frequency region, a model retraining module 600 that retrain the neural network model by using the EIS data of the reduced frequency region, and an SOH diagnosis module 700 that diagnoses the state of the battery by using the retrained neural network model.

The EIS measurement module 200 according to embodiments of the present disclosure may measure EIS data in all of the frequency regions of a battery.

In the process of measuring EIS data, after a current or a voltage is applied, impedance data having a complex number form (i.e., Z=R+jX) may be generated by analyzing a reaction of the battery in the frequency region. The generated data may be converted in a form, such as a Nyquist plot (i.e., a graph of a real number part and an imaginary number part) and a Bode plot (i.e., phase and size information). The EIS measurement module 200 according to embodiments of the present disclosure may measure impedance of the battery in the entire frequency range and collect data in various Soc and temperature conditions.

The model training module 300 according to embodiments of the present disclosure may play a role of training a neural network model that estimates the state of the battery based on the measured EIS data. The neural network model may learn the SOH of the battery by using the SOH data and EIS data of the battery as an input. The neural network model may learn a relation between variables, such as a charging and discharging pattern, a change in internal resistance, and the degradation of an electrode, and the SOH by reflecting degradation characteristics of the battery. The neural network model may include a convolution layer based on a convolutional neural network (CAN) and a fully connected (FC) layer. The overfitting of the neural network model can be prevented by applying a batch normalization or dropout scheme.

The frequency identification module 400 according to embodiments of the present disclosure may perform a role of identifying a frequency region having a high contribution to the prediction of the SOH based on a class activation map (CAM) by using the neural network model.

The process of identifying the frequency region includes a method of selecting a specific frequency point that has an important influence on the prediction of the SOH of the battery based on a CAM score. Whether a specific frequency region provides reliable results in the prediction of the SOH is analyzed by considering the state of charge (SOC) change and temperature conditions of the battery.

It has been demonstrated that the method of reducing the size of data while maintaining performance by selecting only 5 feature frequency points, among 60 or more frequency points, based on CAM scores, instead of using all of frequency data as in the existing method, is effective.

The data dimension reduction module 500 according to embodiments of the present disclosure may perform a role of reducing the data dimension of the identified frequency region by selecting EIS data in the identified frequency region. Operation efficiency can be increased by removing unnecessary frequency data other than selected frequency points based on a CAM. A reduction in the data dimension is to optimize the size of input data so that a neural network model can be trained by using only selected frequency points. Accordingly, it is possible to improve an SOH prediction operation speed and to reduce an SOH measurement time.

The model retraining module 600 according to embodiments of the present disclosure retrains the neural network model by using the EIS data of the reduced frequency region. The neural network model that is optimized to maintain prediction performance of the SOH, while reducing a computational load, compared to the existing neural network model may be trained by using frequency data selected based on the CAM. When compared to the existing neural network model, the neural network model may be retrained in a way to verify performance of the neural network model based on a reduced dataset and to minimize an error of the prediction of the SOH.

The SOH diagnosis module 700 according to embodiments of the present disclosure may perform a role of diagnosing the state of the battery by using the retrained neural network model. The SOH diagnosis module 700 may predict the SOH of the battery by receiving the EIS data of the reduced frequency region as an input and analyze the degradation state of the battery based on the predicted SOH. When an SOH value falls below a predetermined threshold, the SOH diagnosis module 700 may determine that possibility that internal resistance is increased and an electrode is degraded. By analyzing the SOH degradation pattern according the charge/discharge cycles and operating environment of the battery, the SOH diagnosis module 700 may support the establishment of battery replacement, maintenance, and repair strategies.

As described herein, the method of diagnosing the state of a battery according to embodiments of the present disclosure and the apparatus for diagnosing the state of a battery can significantly reduce the time taken to measure EIS data in a process of evaluating the SOH of a battery. In the existing method, approximately 20 to 30 minutes were taken to measure and analyze data in all of frequency regions. In contrast, in embodiments of the present disclosure, the SOH of a battery can be predicted within approximately 14.5 seconds because only major frequency regions are selected and measured.

Furthermore, the state of a battery can be automatically analyzed by using a neural network model. A computational load can be reduced and high prediction accuracy can be maintained through a reduction of a data dimension and a retraining process. Accordingly, it is possible to rapidly evaluate the degradation state of a battery and to effectively predict a battery replacement time.

The method and apparatus according to embodiments of the present disclosure may be used in various application fields, such as an energy storage system (ESS), a drone, and a battery for power network storage, in addition to a battery for an electric vehicle, and can extend the lifespan of a battery and reduce maintenance and repair costs.

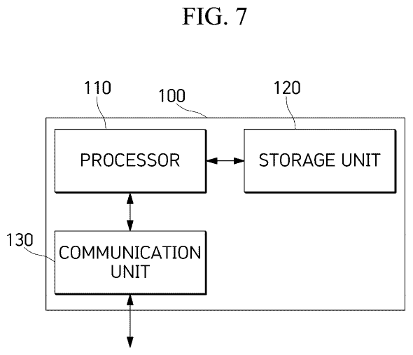

FIG. 7 is a diagram illustrating a construction of an apparatus for implementing the method of diagnosing the state of a battery according to embodiments of the present disclosure.

Referring to FIG. 7, an apparatus 100 for diagnosing the state of a battery may include a processor 110, a storage unit 120, and a communication unit 130.

The processor 110 may perform a role of analyzing measured EIS data by executing a battery state diagnosis algorithm, predicting the SOH of a battery, and processing data. In this case, the processor 110 may perform an operation of analyzing impedance data measured in all of the frequency regions of the battery based on reference data and a threshold stored in the storage unit 120 and identifying frequency points having a high contribution to the prediction of the SOH by using a class activation map (CAM). Furthermore, the processor 110 may reduce the data dimension of the frequency region by using the selected frequency points, and may evaluate the state of the battery by training and retraining a neural network model.

Furthermore, the processor 110 may train the neural network model that predicts the SOH of the battery by receiving impedance data of the battery through the EIS measurement module 200 (including an electrode, a frequency application device, and a measurement sensor) connected to the apparatus 100, and may perform an operation of evaluating the state of the battery by analyzing an impedance change pattern for each frequency region. The result of the prediction of the SOH and the degradation state of the battery may be visually displayed in association with a user terminal.

The storage unit 120 may be a region in which major data of the apparatus 100 are stored, and may store reference SOH data of a battery, analyzed impedance frequency points, an SOH prediction model, neural network training data, battery degradation pattern data, and an SOH evaluation history.

Furthermore, the storage unit 120 may store an SOH prediction model (e.g., a neural network model based on a CNN and an anomaly detection model) based on deep learning. Accordingly, it is possible to support the automatic evaluation and visualization of the state of a battery.

Furthermore, the storage unit 120 may store equivalent circuit model (ECM) analysis information and solid content (SD) information based on measured EIS data in order to support the precise analysis of a change in internal resistance of a battery and of the degradation state of an electrode.

The communication unit 130 may perform a role of transmitting and receiving data between the apparatus 100 and a battery management system (BMS), a user terminal (e. g., a monitoring server or a data analysis system), or a cloud-based database.

The communication unit 130 may transmit SOH diagnosis data in real time and provide analyzed results to a remote server or a user interface (UI), by supporting a wireless communication method, such as Wi-Fi, Bluetooth, LTE, and 5G, and a wired network (e.g., Ethernet and a LAN). Furthermore, the communication unit 130 may enable SOH evaluation reference data to be updated and a new battery degradation pattern to be learnt in association with an external database.

The processor 110 may diagnose the state of a battery based on reference data stored in the storage unit 120 and the SOH prediction model, and may provide analyzed results to a user interface (UI) or a battery management system (BMS) through the communication unit 130.

According to embodiments of the present disclosure, the apparatus 100 may visually provide the diagnosis result of the state of a battery through a user interface (UI). Accordingly, a user can easily check the SOH of a battery, a change in internal resistance Of a battery, and the degradation state of f a battery. To this end, the storage unit 120 may store the SOH prediction model based on a frequency, a data dimension reduction algorithm, an ECM analysis the model, and a neural network training model.

The apparatus 100 may operate in conjunction with a battery management system (BMS), an energy storage device (ESS), an electric vehicle (EV) monitoring system, and a remote data analysis system, and can contribute to the prediction of the lifespan of a battery and the establishment of a maintenance and repair plan by analyzing the state of the battery in real time.

For example, when a battery for an electric vehicle operates conjunction with the apparatus 100 for diagnosing the state of a battery, after the EIS data of the battery that are measured in real time are analyzed by the processor 110, the SOH of the battery is evaluated, and whether the battery has been degraded is determined, corresponding results may be transmitted to a user terminal or a battery management system (BMS).

As described herein, the apparatus for diagnosing the state of a battery according to embodiments of the present disclosure can precisely evaluate the state of a battery by applying EIS-based data analysis and the SOH prediction algorithm based on deep learning-based, and can support efficient operation and maintenance and repair of a battery through real-time data analysis.

Although the present disclosure has been described herein with reference to limited embodiments and the accompanying drawings, the present disclosure is not limited thereto, and various modifications and variations may be made by those skilled in the art within the technical spirit of the present disclosure and the scope of equivalents of the claims set forth herein.

What is claimed is:

1. A method of diagnosing a state of a battery using an apparatus for diagnosing the state of the battery, the method comprising:
measuring electrochemical feature data of all of frequency regions of the battery;
training a neural network model that estimates the state of the battery in the measured electrochemical feature data;
identifying a frequency region having a high contribution to a prediction of the state of the battery based on a feature map by using the trained neural network model;
reducing a data dimension of the frequency region by extracting the electrochemical feature data of the identified frequency region;
retraining the neural network model by using electrochemical feature data of the reduced frequency region; and
diagnosing the state of the battery by using the retrained neural network model.

2. The method as claimed in claim 1, wherein the measuring of the electrochemical feature data comprises:
measuring electrochemical impedance spectroscopy (EIS) data, and
generating impedance data having a complex number form by measuring impedance of an entire frequency range of the battery.

3. The method as claimed in claim 1, wherein the training of the neural network model comprises estimating the state of the battery by using a state of health (SOH) data of the battery and the electrochemical feature data as an input.

4. The method as claimed in claim 3, wherein the training of the neural network model comprises normalizing input data for the neural network model by reflecting a state of charge (SOC) and temperature condition of the battery.

5. The method as claimed in claim 1, wherein the identifying of the frequency region based on the feature map comprises:
identifying the frequency region based on a class activation map (CAM), and
selecting a frequency point having a high contribution to a prediction of a state of health (SOH) through analysis based on a CAM score of the trained neural network model.

6. The method as claimed in claim 5, wherein the identifying of the frequency region based on the feature map comprises selecting the frequency point so that the SOH is able to be reliably predicted even in a specific soc condition by reflecting an impedance feature according to a change in SOC of the battery.

7. The method as claimed in claim 1, wherein the reducing of the data dimension of the frequency region by extracting the electrochemical feature data of the identified frequency region comprises:
removing unnecessary data in the identified frequency region, and
reducing a data dimension by using only selected frequency points.

8. The method as claimed in claim 1, wherein the retraining of the neural network model by using the electrochemical feature data of the reduced frequency region comprises:
retraining the neural network model by using a reduced dataset, and
verifying prediction performance of an SOH of the battery.

9. The method as claimed in claim 8, wherein the retraining of the neural network model comprises performing the retraining in a way to minimize an error of the prediction of the SOH by comparing and evaluating performance of an existing neural network model and performance of a neural network model using the reduced dataset.

10. The method as claimed in claim 1, wherein the diagnosing of the state of the battery by using the retrained neural network model comprises:
predicting an SOH of the battery by receiving the electrochemical feature data of the reduced frequency region as an input, and
analyzing a degradation state of the battery based on the SOH.

11. An apparatus for diagnosing a state of a battery, comprising:
an electrochemical feature data measurement module configured to measure EIS data of all of frequency regions of the battery;
a model training module configured to train a neural network model that estimates the state of the battery in the measured electrochemical feature data;
a frequency identification module configured to identify a frequency region having a high contribution to a prediction of the state of the battery based on a feature map by using the trained neural network model;
a data dimension reduction: module configured to reduce a data dimension of the frequency region by extracting the electrochemical feature data of the identified frequency region;
a model retraining module configured to retrain the neural network model by using electrochemical feature data of the reduced frequency region; and
an SOH diagnosis module configured to diagnose the state of the battery by using the retrained neural network model.

12. The apparatus as claimed in claim 11, wherein the electrochemical feature data measurement module measures EIS data and generates impedance data having a complex number form by measuring impedance of an entire frequency range of the battery.

13. The apparatus as claimed in claim 11, wherein the model training module comprises a neural network model that estimates the state of the battery by SOH data of the battery and the electrochemical feature data as an input.

14. The apparatus as claimed in claim 13, wherein the model training module normalizes input data for the neural network model by reflecting an SOC and temperature condition of the battery.

15. The apparatus as claimed in claim 11, wherein the frequency identification module identifies the frequency region based on a CAM and selects a frequency point having a high contribution to a prediction of an SOH of the battery through analysis based on a CAM score of the trained neural network model.

16. The apparatus as claimed in claim 15, wherein the frequency identification module selects the frequency point so that the SOH is able to be reliably predicted even in a specific SOC condition by reflecting an impedance feature according to a change in SOC of the battery.

17. The apparatus as claimed in claim 11, wherein the data dimension reduction module removes unnecessary data in the identified frequency region and reduces a data dimension by using only selected frequency points.

18. The apparatus as claimed in claim 11, wherein the model retraining module retrains the neural network model by using a reduced dataset and verifies prediction performance of an SOH of the battery.

19. The apparatus as claimed in claim 18, wherein the model retraining module performs the retraining in a way to minimize an error of the prediction of the SOH by comparing and evaluating performance of an existing neural network model and performance of a neural network model using the reduced dataset.

20. The apparatus as claimed in claim 11, wherein the SOH diagnosis module predicts SOH of the battery by receiving the electrochemical feature data of the reduced frequency region as an input and analyzes a degradation state of the battery based on the SOH.
